(19) United States
(12) Patent Application Publication
(10) Pub. No.: US 2007/0111545 A1
(43) Pub. Date: May 17, 2007

(54) Methods of forming silicon dioxide layers using atomic layer deposition

(76) Inventors: Sung-hae Lee, Gyeonggi-do (KR); Ki-hyun Hwang, Gyeonggi-do (KR); Jin-gyun Kim, Gyeonggi-do (KR); Sang-ryol Yang, Gyeonggi-do (KR); Hong-suk Kim, Gyeonggi-do (KR); Jin-tae Noh, Gyeonggi-do (KR)

Correspondence Address: MYERS BIGEL SIBLEY & SAJOVEC, PO BOX 37428, RALEIGH, NC, 27627, US

(21) Appl. No.: 11/521,145

(22) Filed: Sep. 14, 2006

(30) Foreign Application Priority Data
Nov. 16, 2005 (KR) 2005-109522

(51) Int. Cl. H01L 21/31

(52) U.S. Cl. 438/787; 438/788

(57) ABSTRACT

Provided herein are methods of forming a silicon dioxide layer on a substrate using an atomic layer deposition (ALD) method that include supplying a Si precursor to the substrate and forming on the substrate a Si layer including at least one Si atomic layer; and (b) supplying an oxygen radical to the Si layer to replace at least one Si—Si bond within the Si layer with a Si—O bond, thereby oxidizing the Si layer, to form a silicon dioxide layer on the substrate.

### CROSS-REFERENCE TO RELATED PATENT APPLICATION

This application claims the benefit of Korean Patent Application No. 10-2005-0109522, filed on Nov. 16, 2005, in the Korean Intellectual Property Office, the disclosure of which is incorporated by reference herein in its entirety.

### FIELD OF THE INVENTION

The present invention relates to methods of forming a thin film on a substrate, and more particularly, to methods of forming a silicon dioxide layer on a substrate using an atomic layer deposition (ALD) method.

### BACKGROUND OF THE INVENTION

As the size of microelectronic devices decreases, more importance is being placed on the characteristics of the silicon dioxide layers that are applied to gate oxide layers and dielectric layers of field-effect transistors in semiconductor devices.

In processes for fabricating semiconductor devices, silicon dioxide layers may be formed by methods such as thermal chemical vapor deposition (CVD), low pressure CVD (LPCVD) or plasma-enhanced CVD (PECVD). The thermal CVD method may provide suitable step coverage but may also produce defects due to the high temperatures used in the processes. The PECVD method allow for high deposition speeds at low temperatures, but may also produce relatively large numbers of traps in the resultant layer, and additionally, may provide relatively poor step coverage. Accordingly, there may be limitations to the application of these methods to the formation of silicon dioxide layers in semiconductor device structures.

However, as semiconductor devices may have high integration densities, a short channel effect caused by the high temperature CVD process may be problematic, and thus, low temperatures may be desirable in forming the silicon dioxide layer. In addition, increases in the difference in step height between component elements in semiconductor devices may cause a step coverage and pattern loading effect, which may also be problematic. Therefore, a process of forming silicon dioxide layers that improves or eliminates the aforementioned problems is desirable.

To improve the undesirable effects associated with CVD processes, methods of forming silicon dioxide layers by atomic layer deposition (ALD) processes have been suggested. For example, U.S. Pat. No. 6,090,442 discusses a method of forming a silicon dioxide layer by an ALD process using SiCl₄ and H₂O. In this method, a monolayer of one SiO₂ layer is obtained through one deposition cycle of the ALD process. Repeated formation of the SiO₂ monolayer may result in a silicon dioxide layer with a relatively low packing density. Furthermore, the deposition speed of the method may be undesirably low and so may not satisfy throughput requirements for a semiconductor device fabricating processes.

Thus, a method of forming a silicon dioxide layer that may be performed at low processing temperatures, may increase the deposition speed, and may provide a silicon dioxide layer having suitable step coverage, would be desirable.

### SUMMARY OF THE INVENTION

In some embodiments of the present invention, provided is a method of forming a silicon dioxide layer on a substrate including supplying a Si precursor to the substrate and forming on the substrate a Si layer including at least one Si atomic layer; and supplying an oxygen radical to the Si layer to replace at least one Si—Si bond within the Si layer with a Si—O bond, thereby oxidizing the Si layer, to form the silicon dioxide layer on the substrate.

In some embodiments of the invention, supplying a Si precursor to the substrate and forming on the substrate a Si layer including at least one atomic layer includes loading the substrate into a chamber; supplying the Si precursor to the substrate and forming one Si atomic layer on the substrate; removing from the chamber excess Si precursor and any reaction by-products produced during the forming of the one Si atomic layer; supplying hydrogen atoms to the one Si atomic layer; removing from the chamber excess hydrogen and any reaction byproducts produced during the supplying of hydrogen atoms to the one Si atomic layer; and optionally repeating the processes recited above at least once to form the Si layer.

In some embodiments of the invention, the Si layer includes amorphous silicon.

In some embodiments of the invention, the oxygen radical may be generated from an O₂ plasma or ozone.

In some embodiments of the invention, the Si precursor may include at least one of SiCl₄, SiHCl₃, Si₂Cl₆, SiH₂Cl₂, Si₃Cl₈ and Si₃H₈.

In some embodiments of the invention, the Si layer may have a thickness in a range of about 5 to about 100 Å.

Silicon dioxide layers according to some embodiments of the invention may be formed at relatively low process temperatures, may possess a low trap density and may provide enhanced step coverage. In addition, since the Si layer may be oxidized with the highly reactive oxygen radical, the deposition speed of the silicon dioxide layer may be increased, and thus, processing times may be reduced and throughput may be increased.

### BRIEF DESCRIPTION OF THE DRAWINGS

The above and other features and advantages of the present invention will become more apparent by describing in detail exemplary embodiments thereof with reference to the attached drawings in which:

FIG. 1 is a flow diagram illustrating a method of forming a silicon dioxide layer according to an embodiment of the present invention;

FIG. 2 is a flow diagram illustrating an exemplary atomic layer deposition (ALD) method of forming a Si layer that may be used in a method of forming a silicon dioxide layer according to an embodiment of the present invention; and

FIG. 3 is a graph illustrating the oxidation thickness of a silicon layer according to an embodiment of the invention as a function of oxygen plasma supplying time.

### DETAILED DESCRIPTION OF EMBODIMENTS OF THE INVENTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “on” another element or layer, it can be directly on the other element or layer or intervening elements or layers may be present. In contrast, when an element is referred to as being “directly on” another element or layer, there are no intervening elements or layers present.

As used herein, the term “and/or” may include any and all combinations of one or more of the associated listed items.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, processes, elements, and/or components, but do not preclude the presence or addition of one or more other features, integers, steps, processes, elements, components, and/or groups thereof.

Moreover, it will be understood that steps comprising the methods provided herein can be performed independently or at least two steps can be combined when the desired outcome can be obtained. Additionally, steps comprising the methods provided herein, when performed independently or combined, can be performed at the same temperature or at different temperatures without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

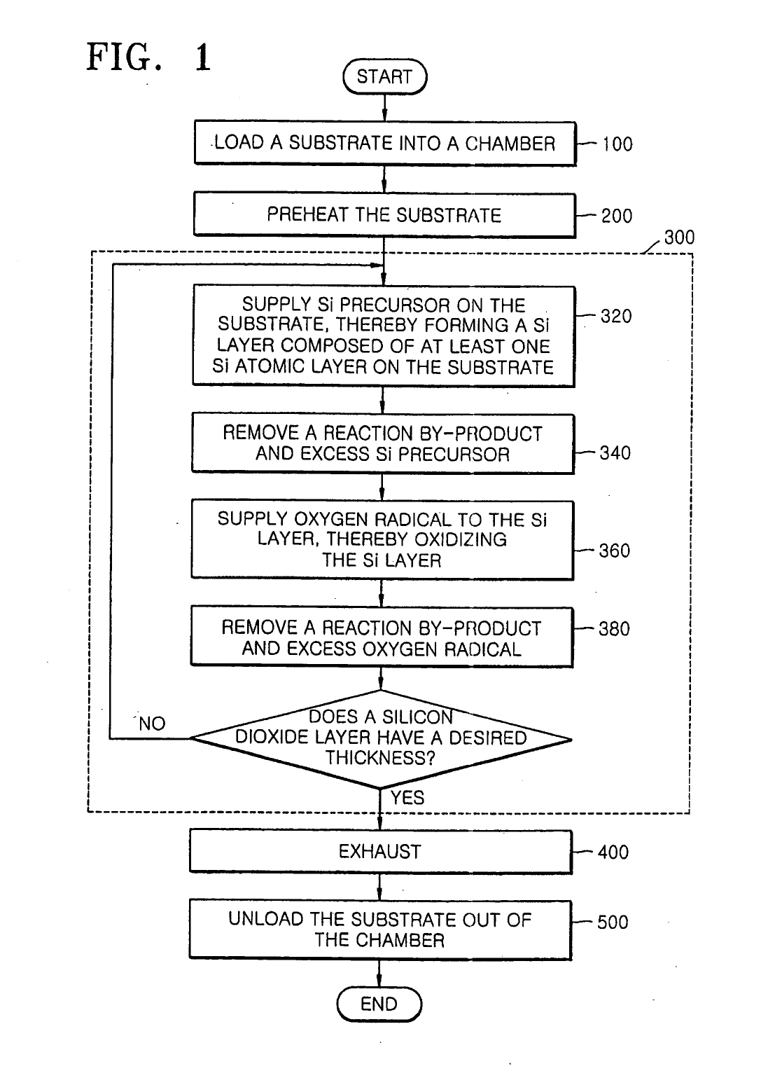

FIG. 1 schematically illustrates a method of forming a silicon dioxide layer on a substrate using an atomic layer deposition (ALD) method according to an embodiment of the invention. Referring to FIG. 1, a substrate onto which a semiconductor device can be formed may be loaded into a chamber, such as a chamber of a thin film formation apparatus (process 100). Subsequently, the substrate may be preheated, for example with a heater installed inside the chamber, to a temperature sufficient to form a silicon dioxide layer according to the an embodiment of the invention (process 200). In some embodiments, the temperature is in a range of about 25 to 800° C.

After the substrate is heated to the desired temperature, a silicon dioxide layer may be formed on the substrate using an ALD method according to an embodiment of the invention, as described in detail below (process 300).

In some embodiments of the present invention, a Si precursor may be supplied to the substrate, and a Si layer including at least one Si atomic layer may be formed on the substrate (process 320). In some embodiments, the thickness of the Si layer may be predetermined.

In some embodiments of the invention, the Si precursor may include at least one of SiCl₄, SiHCl₃, Si₂Cl₆, SiH₂Cl₂, Si₃Cl₈ and Si₃H₈. Furthermore, in some embodiments of the present invention, the Si layer formed may include amorphous silicon, single crystal silicon or polysilicon. In some embodiments, the resulting Si layer includes amorphous silicon. In addition, in some embodiments, the process conditions such as the flow rate of the Si precursor, temperature of the substrate inside the chamber, and pressure inside the chamber are set to relatively high levels, which may increase the reaction rate and facilitate the formation of an amorphous Si layer on the substrate. In some embodiments, the Si layer may have a thickness in a range of about 5 to 100 Å, and in some embodiments, in a range of about 10 to about 30 Å.

In some embodiments of the present invention, the process temperature inside the chamber during the supplying of the Si precursor is maintained at a temperature in a range of about 25 to about 800° C., and in some embodiments, the process temperature is maintained at a temperature in a range of about 300 to 800° C., which may increase the reaction rate and may facilitate the formation of a Si layer with an amorphous structure. However, an amorphous structure may also be formed at lower temperatures, such as between 25 and 300° C., as other process parameters, such as pressure and flow rate of the Si precursor may be controlled to increase a reaction rate such that the Si layer is formed as an amorphous structure.

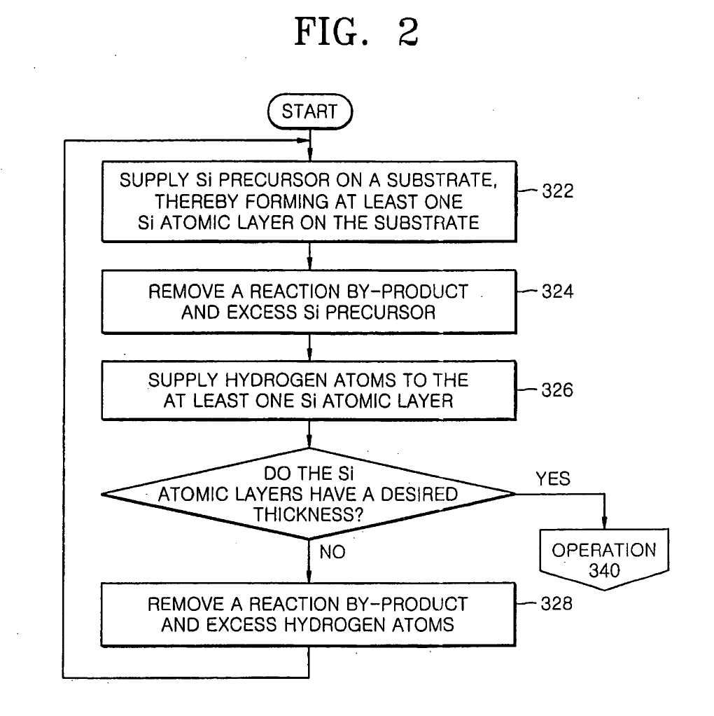

FIG. 2 is a flow diagram illustrating an ALD process, according to some embodiments of the present invention, that may be used to form the Si layer (process 320).

Referring to FIG. 2, the Si precursor may be supplied to a substrate loaded inside a chamber (process 322), so as to form at least one Si atomic layer on the substrate. In some embodiments, the Si precursor may be supplied to a substrate to form one Si atomic layer. In some embodiments of the invention, the Si precursor includes at least one of SiCl₄, SiHCl₃, Si₂Cl₆, SiH₂Cl₂, Si₃Cl₈ and Si₃H₈. When the Si precursor is supplied to the substrate, an inert gas, e.g., argon, may be also supplied to the chamber.

In some embodiments, SiH₂Cl₂ may be used as the Si precursor in process 322. The SiH₂Cl₂ may decompose to form SiHCl gas, and the SiHCl gas may adsorb to the substrate, thus forming a Si atomic layer wherein the chlorine atom bonded to the Si atom may be exposed on the surface of the Si atomic layer.

According to one process 324, excess Si precursor and any by-product produced during the forming of the Si atomic layer may be removed from the chamber. The removal of the excess Si precursor and by-products may be achieved by any suitable method, including purging with an inert gas such as argon, or exhausting the chamber by opening the chamber to a lower pressure outside of the chamber. Furthermore, in some embodiments, the excess Si precursor and by-products may be removed from the chamber by a combination of processes, such as both purging the chamber with an inert gas and exhausting the chamber. For example, in some embodiments, purging with an inert gas may be performed after exhausting the chamber, and in some embodiments, the purging with an inert gas may be performed before exhausting the chamber.

In process 326, hydrogen atoms may be supplied to the Si atomic layer in order to provide a free Si site on the surface of the Si atomic layer. For example, in embodiments wherein SiH₂Cl₂ is used as the Si precursor in process 322, hydrogen atoms may be supplied in process 326 to the Si atomic layer to remove the Cl exposed on the surface of the Si atomic layer.

If the Si layer has the desired thickness after process 326, process 340 of FIG. 1 may then be performed. However, if the Si layer does not have the desired thickness after process 326, the excess hydrogen and any reaction by-products may then be removed from the chamber (process 328). The removal of the excess hydrogen and by-products may be achieved by any suitable method, including any of the methods described with reference to process 324. At this point, processes 322 through 326 may then be repeated at least once until the Si layer on the substrate reaches the desired thickness.

Referring again to FIG. 1, if the Si layer is formed with the desired thickness in process 320, any excess hydrogen or reaction by-products generated during the formation of the Si layer may then be removed from the chamber (process 340). Removal of the excess hydrogen and by-products may be achieved by any suitable method, including any of the methods described with reference to process 324.

An oxygen radical may then be supplied to the Si layer so that at least one Si—Si bond within the Si layer is replaced with a Si—O bond, thereby oxidizing the Si layer (process 360). In some embodiments, the oxygen radical may be generated by an O₂ plasma or by ozone (O₃). In embodiments wherein an O₂ plasma is the source of the oxygen radical, a predetermined radio frequency power may be applied while supplying O₂ to the chamber. As the O₂ plasma or O₃ is generally in an unstable state, it may be highly reactive with the Si layer. By utilizing an O₂ plasma or O₃, a silicon layer having a single crystal structure may also be also oxidized. However, in order to reduce the bond strain created by the change of lattice distances upon oxidation of the Si layer, an amorphous Si layer may be formed in the process 320. Furthermore, amorphous Si layers may be formed at relatively reduced processing temperatures, which may decrease energy costs.

In process 380, excess oxygen or any reaction by-products produced during the oxidation of the Si layer may be removed from the chamber. The removal of the oxygen and/or byproducts may be achieved by any of the methods described with reference to process 324.

Processes 320 through 380 may be repeated at least once until the SiO₂ layer is formed on the substrate with the desired thickness. When the silicon dioxide layer is formed on the substrate with the desired thickness, an exhaust process may be performed to remove any by-products remaining inside the chamber (process 400). The substrate may then be unloaded from the chamber (process 500).

Silicon dioxide layers formed according to some embodiments of the present invention may be employed in various forms in the fabrication of highly-integrated semiconductor devices. For example, in some embodiments, the silicon dioxide layer may be a sidewall spacer on the sidewalls of a gate electrode formed on a semiconductor substrate. In some embodiments, the silicon dioxide layer may be a gate insulating layer on the semiconductor substrate. In some embodiments, the silicon dioxide layer may be a silicide blocking layer. In addition, in some embodiments, the silicon dioxide layer may be a sidewall spacer of a bit line formed on a semiconductor substrate. As another example, the silicon dioxide layer may be an interlayer insulating layer formed on a semiconductor substrate, or an etch preventive layer for protecting a predetermined layer on a semiconductor substrate. When the silicon dioxide layer is used as an etch preventive layer, in some embodiments, the silicon dioxide layer may be used singly, and in other embodiments, a composite layer of the silicon dioxide layer with a silicon nitride layer may be used. More specifically, to prevent or reduce damage to a predetermined layer on the semiconductor substrate during a dry etch process, a silicon nitride layer is generally used as an etch preventive layer during the dry etch process. In order to prevent or reduce a recess phenomenon, which may occur on the surface of the predetermined layer under the silicon nitride layer due, at least in part, to over-etching of the silicon nitride layer, a silicon dioxide layer formed by a method according to some embodiments of the present invention may be formed between the predetermined layer and the silicon nitride layer.

The use of a silicon dioxide layer formed according to some embodiments of the present invention is not limited to the exemplary embodiments described above, as the silicon dioxide layers may be used in various components and processes in semiconductor devices and processes, respectively.

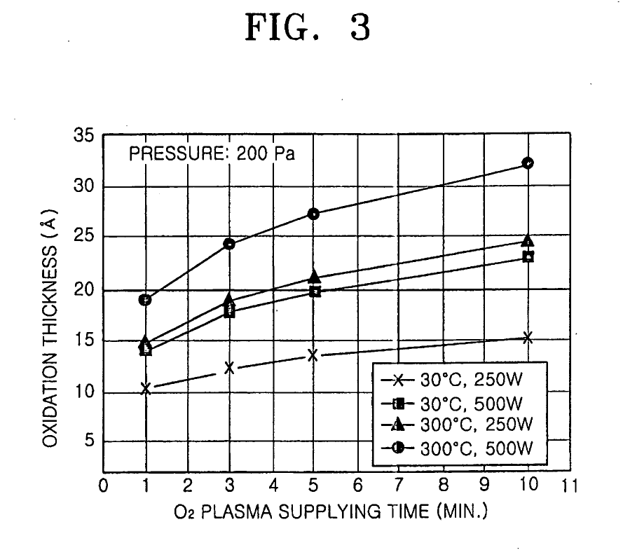

FIG. 3 is a graph illustrating the measurement of the oxidiation thickness of a Si layer formed according to some embodiments of the invention as a function of O₂ plasma exposure time. Referring to FIG. 3, an O₂ plasma was used as the oxygen radical source to oxidize the Si layer. In order to generate the O₂ plasma inside the chamber wherein a wafer having the Si layer formed thereon was loaded, an RF power was applied inside the chamber while O₂ was supplied to the chamber at a flow rate of about 1 slm. The pressure inside the chamber was fixed at 200 Pa, and the oxidation thickness of the Si layer as a function of oxygen plasma supplying time (min) was measured at different RF powers (250 W and 500 W) and different processing temperatures (30° C. and 300° C.). As shown in FIG. 3, the oxidation thickness increased as the process temperature and the RF power increased.

Thus, in a method of forming a silicon dioxide layer using an ALD process according to some embodiments of the present invention, a Si layer including at least one Si atomic layer may be formed, and the Si layer may be oxidized with an oxygen radical. Since the highly reactive oxygen radicals may be used instead of thermal energy, the silicon dioxide layer may be formed at a relatively low process temperature. Furthermore, a silicon dioxide layer formed according to some embodiments of the present invention may have a low trap density compared to a layer formed by a standard PECVD method. A silicon dioxide layer according to some embodiments of the invention may also exhibit improved step coverage. In addition, since the Si layer may be oxidized by a highly reactive oxygen radical, the deposition speed of the silicon dioxide layer may be increased, and thus, a process time may be reduced, thereby increasing throughput.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a silicon dioxide layer on a substrate comprising:
supplying a Si precursor to the substrate and forming on the substrate a Si layer comprising at least one Si atomic layer; and
supplying an oxygen radical to the Si layer to replace at least one Si—Si bond within the Si layer with a Si—O bond, thereby oxidizing the Si layer,
to form the silicon dioxide layer on the substrate.

2. The method of claim 1, wherein the Si precursor comprises at least one compound selected from the group consisting of SiCl₄, SiHCl₃, Si₂Cl₆, SiH₂Cl₂, Si₃Cl₈ and Si₃H₈.

3. The method of claim 1, wherein the oxygen radical is generated from an O₂ plasma or ozone.

4. The method of claim 1, wherein supplying the Si precursor to the substrate and forming on the substrate the Si layer comprising at least one Si atomic layer comprises:
(a) supplying the Si precursor to the substrate and forming at least one Si atomic layer on the substrate;
(b) removing excess Si precursor and any reaction by-products produced during the formation of the at least one Si atomic layer;
(c) supplying hydrogen atoms to the at least one Si atomic layer;
(d) removing excess hydrogen and any reaction byproducts produced during the supply of hydrogen atoms to the at least one Si atomic layer; and optionally
(e) repeating (a) through (d) at least once to form the Si layer on the substrate.

5. The method of claim 1, wherein the Si layer comprises an amorphous silicon layer or a polysilicon layer.

6. The method of claim 1, wherein the Si layer has a thickness in a range of about 5 to about 100 Å.

7. The method of claim 1, wherein supplying the Si precursor to the substrate, forming on the substrate the Si layer and supplying the oxygen radical to the Si layer are performed at a temperature in a range of about 25° C. to about 800° C.

8. The method of claim 1, further comprising repeating supplying the Si precursor, forming on the substrate the Si layer and supplying the oxygen radical to the Si layer, at least once, to form the silicon dioxide layer on the substrate.

9. A method of forming a silicon dioxide layer on a substrate comprising:
supplying a Si precursor to the substrate and forming on the substrate a Si layer comprising at least one Si atomic layer;
removing excess Si precursor and any reaction by-products produced during the formation of the Si layer;
supplying an oxygen radical to the Si layer to replace at least one Si—Si bond within the Si layer with a Si—O bond, thereby oxidizing the Si layer; and
removing excess oxygen radicals and any reaction by-products produced during the oxidation of the Si layer,
to form the silicon dioxide layer on the substrate.

10. The method of claim 9, further comprising repeating supplying the Si precursor to the substrate, removing excess Si precursor and reaction by-products, supplying the oxygen radical to the Si layer and removing excess oxygen and reaction by-products, at least once, to form the silicon dioxide layer on the substrate.

11. The method of claim 9, wherein the Si precursor comprises at least one compound selected from the group consisting of SiCl₄, SiHCl₃, Si₂Cl₆, SiH₂Cl₂, Si₃Cl₈ and Si₃H₈.

12. The method of claim 9, wherein the oxygen radical is generated from an O₂ plasma or ozone.

13. The method of claim 12, wherein the supplying of the oxygen radical comprises applying a radio frequency (RF) power while supplying O₂.

14. The method of claim 9, wherein supplying the Si precursor to the substrate and forming on the substrate the Si layer comprising at least one Si atomic layer comprises
(a) supplying the Si precursor to the substrate and forming at least one Si atomic layer on the substrate;
(b) removing excess Si precursor and any reaction by-products produced during the formation of the at least one Si atomic layer;
(c) supplying hydrogen atoms to the at least one Si atomic layer;
(d) removing excess hydrogen and any reaction byproducts produced during the supply of the hydrogen atoms to the at least one Si atomic layer; and optionally
(e) repeating (a) through (d) at least once to form the Si layer.

15. The method of claim 9, wherein supplying the Si precursor to the substrate, removing excess Si precursor and reaction by-products, supplying hydrogen atoms to the at least one Si atomic layer and removing excess hydrogen and reaction by-products are performed at a temperature in a range of about 25° C. to about 800° C.

16. The method of claim 9, wherein the removal of the excess Si precursor and any reaction by-products produced during the formation of the Si layer and the removal of the excess oxygen radicals and any reaction by-products produced during the oxidation of the Si layer are each independently performed by purging with an inert gas; exhausting; or a combination thereof.

17. The method of claim 9, wherein the Si layer comprises an amorphous silicon layer.

18. The method of claim 9, wherein the Si layer has a thickness in a range of about 5 Å to about 100 Å.
